(19) United States
(12) Patent Application Publication
(10) Pub. No.: US 2025/0299757 A1
(43) Pub. Date: Sep. 25, 2025

(54) EVALUATION METHOD AND EVALUATION DEVICE

(71) Applicant: Kioxia Corporation, Tokyo (JP)

(72) Inventor: Masato IGARASHI, Kawasaki Kanagawa (JP)

(21) Appl. No.: 19/061,105

(22) Filed: Feb. 24, 2025

(30) Foreign Application Priority Data
Mar. 21, 2024 (JP) 2024-045369

(51) Int. Cl. G11C 29/08

(52) U.S. Cl. CPC G11C 29/08

(57) ABSTRACT

An evaluation method includes acquiring first information indicating a state of a defect of a defect of a semiconductor device; generating third information including a location of a failure and a type of the failure in the semiconductor device based on the first information and prestored second information, the prestored second information indicates that the location of the failure and the type of the failure are associated with the first information; controlling whether fourth information for specifying the type of the failure of the semiconductor device is returned to a control device for controlling the semiconductor device, based on an access request from the control device and the third information; and evaluating an operation of the control device after the fourth information is returned.

### CROSS-REFERENCE TO RELATED APPLICATION

This application is based upon and claims the benefit of priority from Japanese Patent Application No. 2024-045369, filed Mar. 21, 2024, the entire contents of which are incorporated herein by reference.

### FIELD

Embodiments described herein relate generally to an evaluation method and an evaluation device.

### BACKGROUND

A non-volatile memory represented by a NAND flash memory may have a concern that the reliability of writing, reading, and erasing data may be reduced due to the miniaturization of a design rule, three-dimensionality, and multi-valuing. In addition, as the capacity of the non-volatile memory increases, a large amount of time is required for operation verification of the non-volatile memory, a device for controlling the non-volatile memory, or a device equipped with the non-volatile memory as a storage medium.

For example, in a controller that controls the non-volatile memory, operation verification tends to be complicated due to multi-functionalization. In particular, in order to perform the operation verification of the controller when the non-volatile memory has some kind of failure, the non-volatile memory must be set to a state of a failure. As the non-volatile memory is highly integrated and increased in capacity, a type of the failure of the non-volatile memory and the location where the failure may occur increase, and thus, it goes into more difficult to verify the operation of the controller when the non-volatile memory fails. The evaluation of a semiconductor device, not limited to the non-volatile memory, goes into difficult as the semiconductor device is highly integrated and multifunctional.

### DESCRIPTION OF THE DRAWINGS

FIG. 1 is a block diagram illustrating a schematic configuration of an evaluation system including an evaluation device according to one embodiment.

FIG. 2 is a block diagram illustrating an example of a detailed configuration of a memory control simulation unit.

FIG. 3 is a diagram illustrating an example of a fault dictionary.

FIG. 4 is a block diagram illustrating a functional configuration of a fault information generation unit.

FIG. 5 is a diagram illustrating a processing operation of the fault information generation unit.

FIG. 6 is a diagram illustrating an example of a correspondence relationship between wiring defect information and fault injection information.

FIG. 7 is a flowchart illustrating a processing operation of an evaluation system according to the present embodiment.

### DETAILED DESCRIPTION

Embodiments provide an evaluation method and an evaluation device capable of efficiently evaluating a semiconductor device.

In general, according to one embodiment, there is provided an evaluation method including acquiring first information indicating a state of a defect of a defect of a semiconductor device; generating third information including a location of a failure and a type of the failure in the semiconductor device based on the first information and prestored second information, wherein the prestored second information indicates that the location of the failure and the type of the failure are associated with the first information; controlling whether fourth information for specifying the type of the failure of the semiconductor device is returned to a control device, based on an access request from the control device for controlling the semiconductor device and the third information; and evaluating an operation of the control device after the fourth information is returned.

Hereinafter, embodiments of the evaluation method and the evaluation device according to the embodiments will be described with reference to the drawings. In the following, description will be provided centered on main configuration portions of the evaluation method and the evaluation device, but the evaluation method and the evaluation device may include components or functions that are not illustrated or described. The following description does not exclude the components or the functions not illustrated or described.

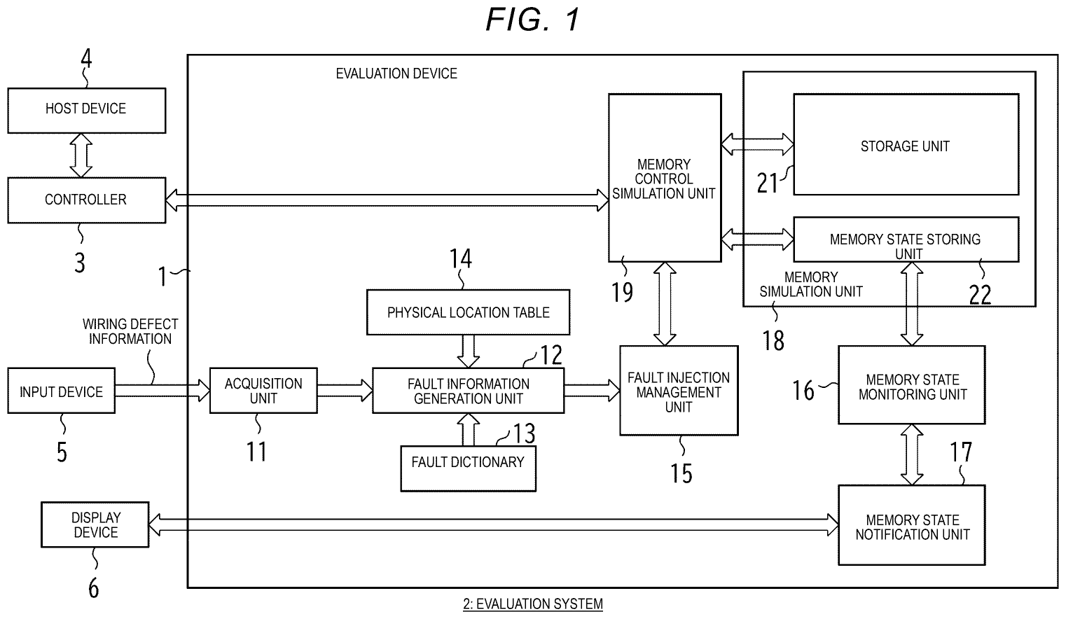

FIG. 1 is a block diagram illustrating a schematic configuration of an evaluation system 2 including an evaluation device 1 according to one embodiment. The evaluation system 2 in FIG. 1 evaluates a controller 3 that controls a NAND flash memory, and hereinafter, the evaluation system 2 may be referred to as a virtual NAND system. The evaluation device 1 according to one embodiment can also be applied in a case of evaluating a control device that controls various semiconductor devices other than the controller 3 that controls the NAND flash memory. In the following description, the NAND flash memory is simply referred to as a flash memory.

The evaluation system 2 including the evaluation device 1 according to one embodiment illustrated in FIG. 1 includes the evaluation device 1, a controller 3, a host device 4, and an input device 5.

The controller 3 is configured to control the flash memory. More specifically, the controller 3 can perform access such as writing, reading, erasing, or verifying to the flash memory. The evaluation device 1 according to one embodiment evaluates an operation of the controller 3 in a design stage or a manufacturing stage of the controller 3, or the like. More specifically, the evaluation device 1 according to one embodiment evaluates an operation of the controller 3 when there is a failure in the flash memory. In order to evaluate the operation of the controller 3 when there is a failure in the flash memory, it is necessary to evaluate the operation of the controller 3 in a state where there is a failure in the flash memory. Therefore, in the present embodiment, the operation of the controller 3 is evaluated after a state of the failure of the flash memory is virtually generated.

The evaluation device 1 according to one embodiment can evaluate not only the evaluation of the controller 3 but also an operation of an inspection device that inspects the flash memory. For example, the evaluation device 1 according to one embodiment can evaluate the operation of the inspection device when a flash memory is failed. The inspection device in this case is connected to a memory control simulation unit 19 in the evaluation device 1, as in the same manner as the controller 3 in FIG. 1.

The controller 3 sends a physical address and a command when accessing the flash memory. In the evaluation device 1 according to the present embodiment, the controller 3 accesses a memory simulation unit 18 that simulates the operation of the flash memory. The controller 3 performs an operation different from an operation in a normal case when the flash memory is abnormal. When the controller 3 accesses the memory simulation unit 18 via the memory control simulation unit 19, the evaluation device 1 according to the present embodiment responds to the controller 3 with information for specifying a type of the failure of the memory simulation unit 18, and then evaluates the operation of the controller 3.

The host device 4 controls the controller 3. For example, the host device 4 transmits an instruction to the controller 3 that access such as writing, reading, or erasing to the flash memory, or the like occurs. In addition, the host device 4 may receive an evaluation result of the flash memory the evaluation device 1.

The input device 5 inputs (or provides) defect information to the evaluation device 1. The defect information is, for example, wiring defect information of the flash memory. The defect information may include various defect information of the flash memory other than the wiring defect information. The input device 5 is provided separately from the controller 3 and the host device 4. The input device 5 may be, for example, an electronic device such as a general-purpose personal computer (PC).

A display device 6 can be connected to the evaluation device 1 as necessary. The display device 6 can display an operation state of the evaluation device 1. The display device 6 is, for example, a logger or a debugger. As described above, the evaluation device 1 can evaluate an operation of the display device 6 when the flash memory is failed.

The evaluation device 1 according to one embodiment includes an acquisition unit (or acquirer) 11, a fault information generation unit 12, a fault dictionary (first storage unit or first storage device) 13, a physical location table (second storage unit or second storage device) 14, a fault injection management unit 15, a memory state monitoring unit 16, a memory state notification unit 17, the memory simulation unit 18, and the memory control simulation unit 19.

The acquisition unit 11 acquires defect information input from the input device 5. The fault information generation unit 12 generates fault injection information related to a failure in the flash memory by referring to the fault dictionary 13 based on the acquired defect information. More specifically, the fault injection information includes a physical address indicating a location of a failure of the flash memory and a type of the failure. The location of the failure indicates a location where the failure occurs in the flash memory.

Here, the defect in the present embodiment refers to, for example, that the electrical characteristics of various members included in the flash memory are abnormal (that is, not normal). In a more specific example, the defect refers to a resistance value of a specific wiring in the flash memory being out of a normal value. The member to be a target of the defect may include not only the wiring but also an active component such as a transistor, or may include a passive component such as a resistor, a capacitor, or inductor. The electrical characteristic to be a target of the defect is a resistance value, a capacitance, an inductance, a current value, a voltage value, or the like.

The failure in the present embodiment is an abnormal operation caused by defects of various members included in the flash memory. For example, the failure in the present embodiment includes at least one of a write abnormality, a read abnormality, and an erase abnormality in the flash memory. The write abnormality includes, for example, an abnormality called program disturb. The program disturb is an abnormality in which a threshold voltage of a non-write target memory cell connected to a word line common to or adjacent to a memory cell of a writing target t is increased, and is a factor of erroneous writing.

The fault dictionary 13 stores a correspondence relationship between a state of the defect of the flash memory, a type of the failure, and a location of the failure of the flash memory. The fault dictionary 13 is configured with, for example, a non-volatile memory.

The physical location table 14 stores a correspondence relationship between the location of the failure stored in the fault dictionary 13 and a physical address. The physical location table 14 is configured with, for example, a non-volatile memory.

The fault information generation unit 12 searches the fault dictionary 13 based on the defect information, and searches the physical location table 14 from the location of the failure searched. The fault information generation unit 12 generates fault injection information including the physical address with the failure and the type of the failure corresponding to the defect information, based on the search result.

The fault injection management unit 15 performs control of transmitting the fault injection information to the memory control simulation unit 19 to store the fault injection information. In the present specification, transmitting the fault injection information to the memory control simulation unit 19 to store the information may be referred to as “injection”. The fault injection management unit 15 also manages the fault injection information transmitted to and stored in the memory control simulation unit 19.

The memory state monitoring unit 16 monitors an operation of the memory simulation unit 18. For example, the memory state monitoring unit 16 monitors a failure simulated by the memory simulation unit 18.

The memory state notification unit 17 outputs operation information, which is a monitoring target of the memory simulation unit 18 monitored by the memory state monitoring unit 16, to the display device 6. In addition, the memory state notification unit 17 sends an instruction signal from the display device 6 to the memory state monitoring unit 16.

The memory simulation unit 18 simulates an operation of the flash memory. The controller 3 accesses the memory simulation unit 18 with a physical address and a command to be given to the flash memory.

The memory simulation unit 18 has a storage unit 21 and a memory state storing unit 22.

The storage unit 21 is configured with, for example, a dynamic random access memory (DRAM). In the DRAM and the flash memory, the configuration of the physical address is different, so that address conversion is performed by a configuration to be described later included in the memory control simulation unit 19. A memory access control unit is provided in, for example, the memory control simulation unit 19. The physical address included in the access request to the flash memory by the controller 3 is converted into a physical address of the DRAM by an address conversion unit. It is desirable to provide a data conversion unit when a data configuration is different between the DRAM and the flash memory.

The memory state storing unit 22 stores defect information or the like that may occur in the flash memory.

The memory control simulation unit 19 simulates various pieces of information that are communicated between the controller 3 and the memory simulation unit 18.

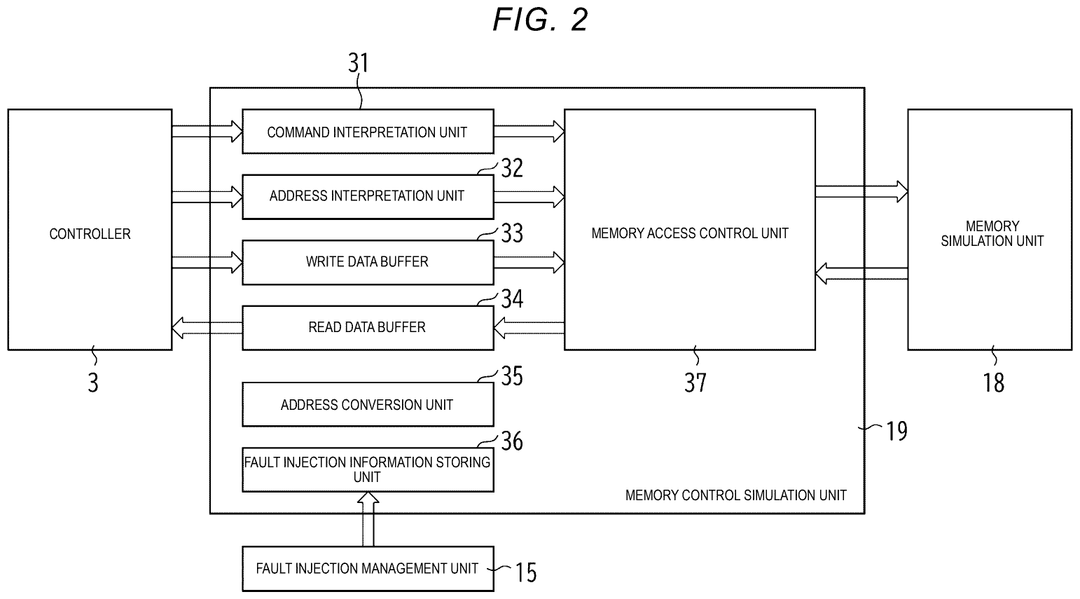

FIG. 2 is a block diagram illustrating an example of a detailed configuration of the memory control simulation unit 19. As illustrated in FIG. 2, the memory control simulation unit 19 includes a command interpretation unit 31, an address interpretation unit 32, a write data buffer 33, a read data buffer 34, an address conversion unit 35, a fault injection information storing unit 36, and a memory access control unit 37. Each of the units 34 to 37 in the memory control simulation unit 19 is configured with at least one of hardware and software.

The command interpretation unit 31 interprets a command sent from the controller 3. The type of the command issued by the controller 3 is not limited, but includes, for example, a write command, a read command, an erase command, and the like for the memory.

The address interpretation unit 32 interprets a physical address sent from the controller 3. When the flash memory has a three-dimensional structure, a part of a bit string configuring the physical address may represent a plane, a block, a page, or the like, and the configuration of the physical address varies depending on the type of the flash memory. The address interpretation unit 32 interprets the physical address according to the type of the flash memory.

The write data buffer 33 buffers write data sent from the controller 3 and sends the buffered data to the memory simulation unit 18. The read data buffer 34 buffers the read data read from the memory simulation unit 18 and sends the buffered data to the controller 3.

The fault injection information storing unit 36 checks whether the physical address sent from the controller 3 is included in a physical address range included in the fault injection information that is transmitted from the fault injection management unit 15 and stored therein, and when the physical address is included, the fault injection information storing unit 36 returns information for specifying the type of the failure included in the fault injection information to the controller 3. Thereby, the controller 3 grasps that there is a failure in a response to the physical address to be accessed, that is, the response is not normal, and executes an operation in a case of the failure.

In this way, the evaluation device 1 returns the failure corresponding to the defect information input from the input device 5 to the controller 3, causes the controller 3 to perform an operation when the flash memory has the failure corresponding to the defect information, and evaluates the operation.

The memory access control unit 37 controls writing and reading of data to and from the storage unit 21 with respect to the physical address interpreted by the address interpretation unit 32 in accordance with the command interpreted by the command interpretation unit 31.

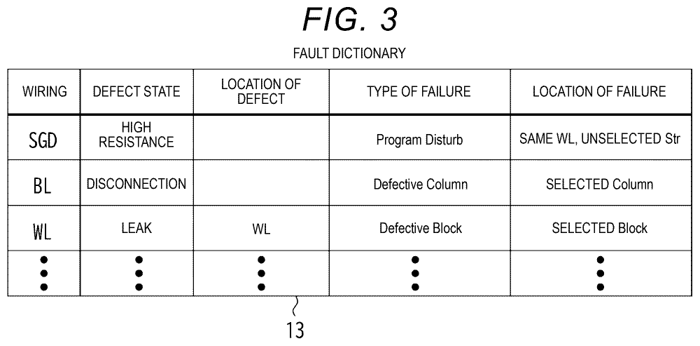

FIG. 3 is a diagram illustrating an example of the fault dictionary 13. As illustrated in FIG. 3, the fault dictionary 13 stores, for example, a type of a wiring in which a defect occurs, a state of the defect, a location of the defect, a type of the failure, and a location of the failure of the flash memory in association with each other. As illustrated in FIG. 3, at least one of the type of the wiring and the information on the location of the defect can be omitted from the fault dictionary 13. In the present specification, information in which the type of the wiring in which the defect occurs, the state of the defect, the location of the defect, the type of the failure, and the location of the failure of the flash memory that are associated with each other, and that is stored in the fault dictionary 13 is referred to as fault information.

The fault information in the first line of FIG. 3 illustrates an example in which a select gate line SGD has a high resistance. This case illustrates that a program disturb occurs in an unselected string Str connected to the same word line WL.

The fault information in the second line of FIG. 3 illustrates an example in which a disconnection occurs in a wiring of a bit line BL. In this case, a selected column in which the disconnection occurs is handled as a defective column. The defective column is a column in which data writing and reading are prohibited.

The fault information in the third line of FIG. 3 indicates that a leak occurs in the word line WL. In this case, a selected block is handled as a defective block. The defective block is a block in which data writing and reading are prohibited. A plurality of strings are included in one block.

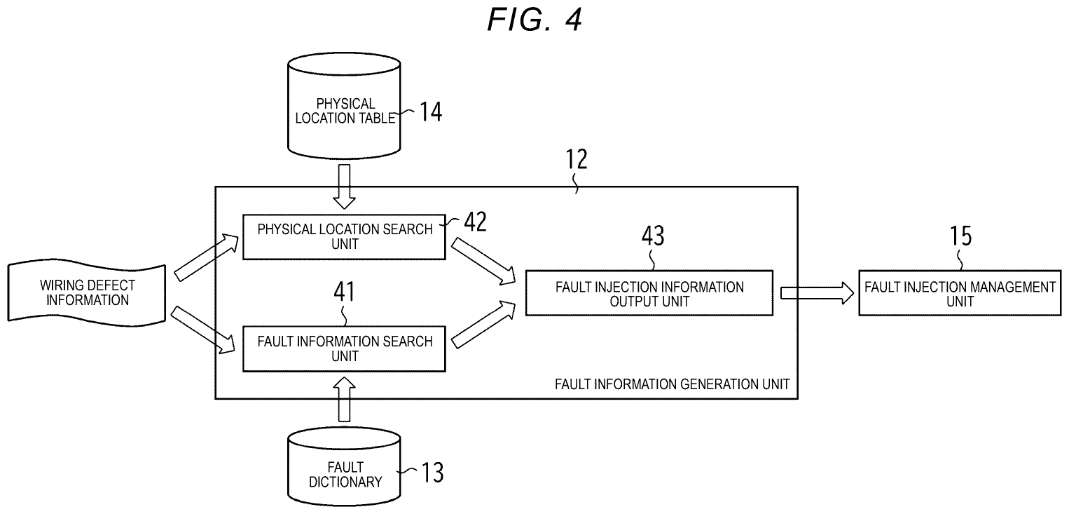

FIG. 4 is a block diagram illustrating a functional configuration of the fault information generation unit 12. The fault information generation unit 12 has a fault information search unit 41, a physical location search unit 42, and a fault injection information output unit 43. As illustrated in FIG. 4, wiring defect information is input to the fault information generation unit 12.

The fault information search unit 41 refers to the fault dictionary 13 and searches fault information corresponding to the input wiring defect information. As a result, the type of the failure corresponding to the input wiring defect information and the location of the failure of the flash memory are obtained.

The physical location search unit 42 searches the physical location table 14 for the physical address range corresponding to the location with the failure searched by the fault information search unit 41.

The fault injection information output unit 43 generates the fault injection information based on a search result of each of the fault information search unit 41 and the physical location search unit 42, and outputs the fault injection information. The fault injection information output from the fault injection information output unit 43 is provided to the fault injection management unit 15.

An example of the wiring defect information input from the input device 5 is information that a specific select gate line has a high resistance. The select gate line is connected to a gate of a select transistor provided in each of the plurality of strings configuring the block. The size and electrical characteristics of the select transistor provided in each string are changed due to variations in the manufacturing process and the like. As a result, a specific select gate line may have a higher resistance than that of other select gate lines. When the select gate line has the high resistance, a voltage level of the bit line may change, and a threshold of the memory cell transistor provided in each string may change. More specifically, when the select gate line has the high resistance, there is a concern that data may be mistakenly written into each memory cell transistor in a string of a non-write target.

A voltage of the select gate line having a low resistance rapidly decreases after a precharge period ends, while a voltage of the select gate line having a high resistance hardly decreases even after the precharge period ends. Therefore, there is a concern that program disturb in which the data is written may occur in the memory cell of the non-write target.

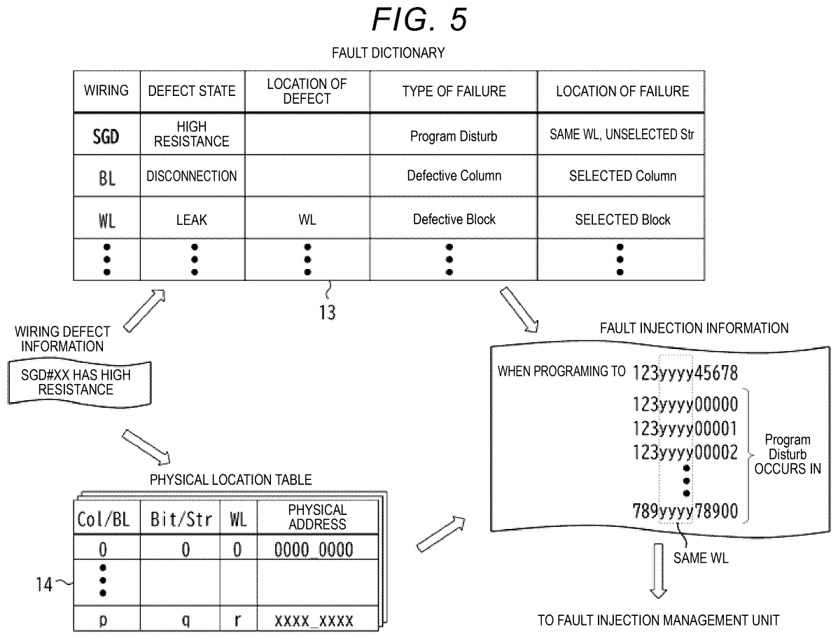

FIG. 5 is a diagram illustrating a processing operation of the fault information generation unit 12. FIG. 5 illustrates an example in which the wiring defect information input from the input device 5 specifies the select gate line SGD having a high resistance. In this case, the fault information generation unit 12 refers to the fault dictionary 13 and searches the fault information of which the program disturb occurs in the string Str which is the non-write target and which is connected to the same word line WL when the select gate line SGD has a high resistance.

The fault information generation unit 12 specifies the string Str having the select gate line SGD from the identification number of the select gate line SGD included in the input wiring defect information, and specifies the physical address range in which program disturb occurs by referring to the physical location table 14 from the specified string Str. The fault information generation unit 12 generates fault injection information indicating that program disturb occurs in the specified physical address range, as illustrated in FIG. 5. As illustrated in FIG. 5, the fault injection information is information in which the physical address range is associated with the type of the defect.

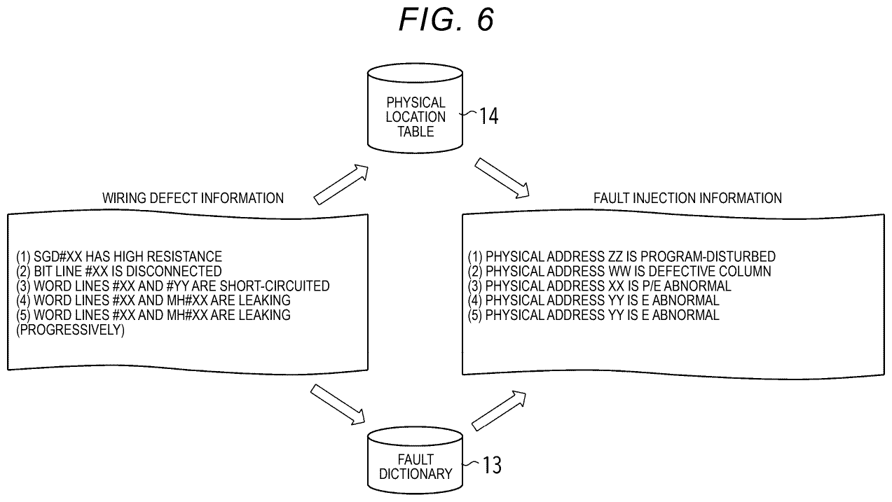

The fault injection information changes in accordance with defect information (for example, wiring defect information) input from the input device 5. FIG. 6 is a diagram illustrating an example of a correspondence relationship between the wiring defect information and the fault injection information. FIG. 6 illustrates an example in which five pieces of fault injection information are input, but these are only examples.

The wiring defect information in (1) indicates that a specific select gate line SGD #XX has a high resistance, as described above. In this case, the fault injection information indicating that program disturb occurs at the physical address “ZZ” indicating the string Str which is the non-write target on the word line WL intersecting the string Str connected to the select gate line SGD is generated.

The wiring defect information of (2) indicates that a specific bit line BL #XX is disconnected. In this case, the fault injection information indicating that the specific physical address “WW” is a defective column is generated.

The wiring defect information of (3) indicates that a specific word lines WL #XX and #YY are short-circuited. In this case, fault injection information indicating that an abnormality occurs in writing and erasing at a specific physical address “XX” is generated.

The wiring defect information of (4) indicates that a specific word line WL #XX and a specific memory hole #XX are leaking. In this case, the fault injection information indicating that the abnormality occurs in erasing at a specific physical address “YY” is generated.

The wiring defect information of (5) indicates that a specific word line WL #XX and a specific memory hole #XX are leaking progressively. In this case, the fault injection information indicating that the abnormality occurs in erasing after the erasing is performed a certain number N of times for a specific physical address “YY” is generated.

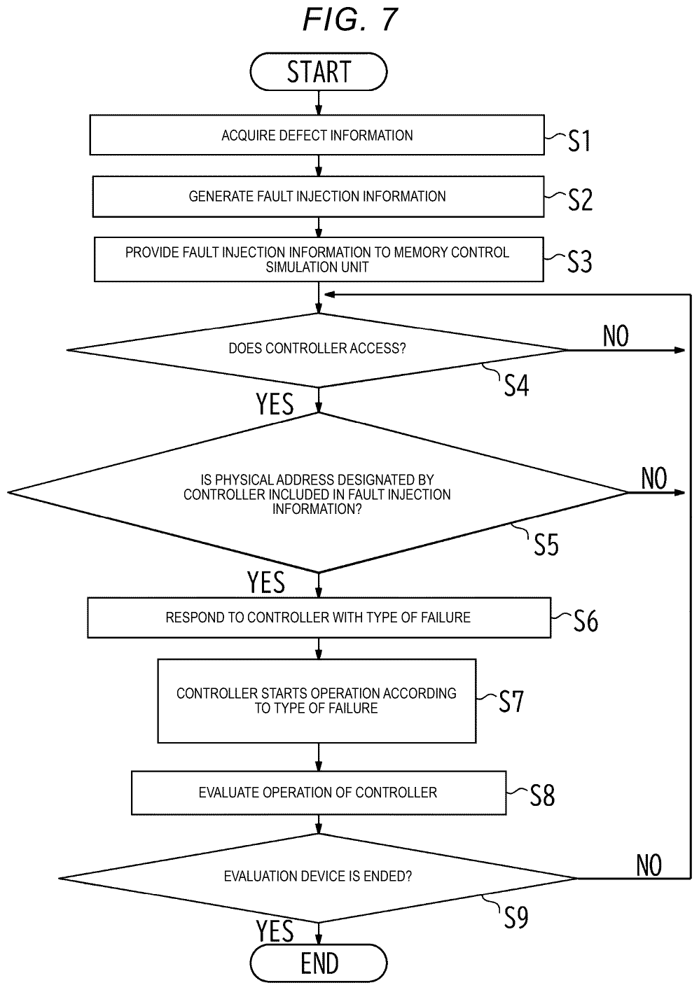

FIG. 7 is a flowchart illustrating a processing operation of the evaluation system 2 according to the present embodiment. In starting the processing of the flowchart in FIG. 7, the fault dictionary 13 stores fault information as illustrated in FIG. 3 in advance, and the physical location table 14 stores a correspondence relationship between a location of a failure stored in the fault dictionary 13 and a physical address in advance.

First, the acquisition unit 11 acquires the defect information input from the input device 5 (S1). Next, the fault information generation unit 12 generates the fault injection information including a location of a failure and a type of the failure in the flash memory by referring to the fault dictionary 13 based on the acquired defect information (S2). Next, the fault injection management unit 15 provides the generated fault injection information to the memory control simulation unit 19 (S3). The memory control simulation unit 19 stores the fault injection information from the fault injection management unit 15 in the fault injection information storing unit 36.

After that, the evaluation device 1 waits until the controller 3 accesses the flash memory (S4). When the controller 3 accesses the flash memory using the physical address and the command (S4 is YES), the memory access control unit 37 determines whether the physical address designated by the controller 3 is included in the fault injection information (S5). When it is determined that the designated physical address is included (S5 is YES), the information for specifying the type of the failure corresponding to the physical address is extracted from the fault injection information and returned to the controller 3 (S6).

When the controller 3 receives information for specifying the type of the failure from the evaluation device 1, the controller 3 starts an operation according to the type of the failure (S7). The evaluation device 1 evaluates the operation of the controller 3 (S8). Thereafter, it is determined whether the evaluation device 1 is ended (S9). Here, the end of the evaluation device 1 refers to, for example, turning off the power of the evaluation device 1 or completing the processing operation by the evaluation device 1. The processing of S4 to S8 is repeated until the processing operation of the evaluation device 1 is ended. On the other hand, in S5, when it is determined that the designated physical address is not included (S5 is NO), the controller 3 waits until the flash memory is accessed (S4).

The processing from S1 in FIG. 7 is started each time the input device 5 inputs new defect information. Further, while the evaluation device 1 starts up, the evaluation device 1 waits for a command from the controller 3, and when a command is input, processing after S4 in FIG. 7 is performed.

In this way, in the present embodiment, the input device 5 provides the evaluation device 1 with the defect information in order to evaluate the operation of the controller 3 when the flash memory has some failure. The defect information is information indicating a state of a defect occurring in a specific member disposed at a specific location of the flash memory. Since the defect information does not include the physical address information of the flash memory, a user is less burdened in generating the defect information.

The fault information generation unit 12 in the evaluation device 1 refers to the fault dictionary 13 based on the defect information input from the input device 5 to search for the type of the failure of the flash memory and the location of the failure of the flash memory. The fault information generation unit 12 refers to the physical location table 14 from the location where the failure occurs to search for a range of the physical address, and generate the fault injection information based on the information searched from the fault dictionary 13 and the physical location table 14. The generated fault injection information is provided to the memory control simulation unit 19 via the fault injection management unit 15. When the physical address included in the access request by the controller 3 is included in the physical address range of the fault injection information, the memory control simulation unit 19 returns information for specifying the type of the corresponding failure to the controller 3. Thereby, the controller 3 performs an operation on the flash memory that is failed, and the evaluation device 1 can evaluate the operation.

As described above, according to the present embodiment, it is easy to virtually create a state in which there is some failure in the flash memory, and the operation of the controller 3 when there is some failure in the flash memory can be correctly evaluated.

The evaluation device 1 according to the present embodiment can be used, for example, for the operation verification of the controller 3 in the design stage of the controller 3. The evaluation device 1 can also be used for the operation evaluation of the controller 3 in the manufacturing stage of the controller 3.

At least a part of the evaluation device 1 described in the above-described embodiment may be configured with hardware or may be configured with software. When being configured with software, a program for implementing at least a part of the functions of the evaluation device 1 may be stored in a recording medium such as a flexible disk or a CD-ROM and may be read by a computer and executed. The recording medium is not limited to a removable medium such as a magnetic disk or an optical disk but may be a fixed recording medium such as a hard disk device or a memory.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An evaluation method comprising:
acquiring first information indicating a state of a defect of a defect of a semiconductor device;
generating third information including a location of a failure and a type of the failure in the semiconductor device based on the first information and prestored second information, wherein the prestored second information indicates that the location of the failure and the type of the failure are associated with the first information;
controlling whether fourth information for specifying the type of the failure of the semiconductor device is returned to a control device for controlling the semiconductor device, based on an access request from the control device and the third information; and
evaluating an operation of the control device after the fourth information is returned.

2. The evaluation method according to claim 1,
wherein the second information further indicates a correspondence relationship between a member to be a target of another defect, a state of the defect, the type of the failure, and the location of the failure of the semiconductor device.

3. The evaluation method according to claim 1,
wherein the third information includes a physical address indicating the location of the failure of the semiconductor device and the type of the failure.

4. The evaluation method according to claim 3,
wherein when the third information includes the physical address of the semiconductor device included in the access request from the control device, the fourth information is returned to the control device.

5. The evaluation method according to claim 3, further comprising:
generating the third information by referring to information configured to specify the physical address, in addition to based on the first information and the second information.

6. The evaluation method according to claim 1,
wherein the first information includes a state of the defect occurring in a specific member disposed at a specific location of the semiconductor device.

7. The evaluation method according to claim 1,
wherein the semiconductor device is a semiconductor memory, and
information for specifying a type of a corresponding failure included in the third information is returned to the control device in response to the control device accessing the semiconductor memory by designating a physical address included in the third information.

8. The evaluation method according to claim 7,
wherein the semiconductor device is a semiconductor memory,
the type of the failure includes at least one of a write abnormality, a read abnormality, or an erase abnormality in the semiconductor memory, and
the control device is configured to control access of the semiconductor memory.

9. The evaluation method according to claim 1,
wherein a correspondence relationship between the state of the defect, the type of the failure, and the location of the failure of the semiconductor device are stored in a first storage device, and a physical location of the semiconductor device corresponding to the location of the failure is stored in a second storage device.

10. The evaluation method according to claim 1,
Wherein the first information includes at least one of a defect of a resistance value, a disconnection of a specific wiring, a short circuit, or a leak of a specific wiring.

11. An evaluation device comprising:
an acquirer configured to acquire first information indicating a state of a defect of a defect of a semiconductor device;
a first storage device configured to store a correspondence relationship between the state of the defect, a type of a failure, and a location of the failure of the semiconductor device;
a second storage device configured to store a physical location of the semiconductor device corresponding to the location of the failure; and
a control circuit configured to:
generate third information including the location of the failure and the type of the failure in the semiconductor device by referring to the first storage device and the second storage device based on the first information;
control whether to return fourth information for specifying the type of the failure of the semiconductor device to a control device for controlling the semiconductor device based on an access request from the control device and the third information; and
evaluate an operation of the control device after the fourth information is returned.

12. The evaluation device according to claim 11,
wherein the second information further indicates a correspondence relationship between a member to be a target of another defect, a state of the defect, the type of the failure, and the location of the failure of the semiconductor device.

13. The evaluation device according to claim 11,
wherein the third information includes a physical address indicating the location of the failure of the semiconductor device and the type of the failure.

14. The evaluation device according to claim 13,
wherein when the third information includes the physical address of the semiconductor device included in the access request from the control device, the fourth information is returned to the control device.

15. The evaluation device according to claim 13, wherein, the control circuit is configured to:
generate the third information by referring to information configured to specify the physical address, in addition to based on the first information and the second information.

16. The evaluation device according to claim 11,
wherein the first information includes a state of the defect occurring in a specific member disposed at a specific location of the semiconductor device.

17. The evaluation device according to claim 16,
wherein the specific member includes a specific wiring disposed at a specific location of the semiconductor device.

18. The evaluation device according to claim 11,
wherein the semiconductor device is a semiconductor memory, and
information for specifying a type of a corresponding failure included in the third information is returned to the control device in response to the control device accessing the semiconductor memory by designating a physical address included in the third information.

19. The evaluation device according to claim 18,
wherein the semiconductor device is a semiconductor memory,
the type of the failure includes at least one of a write abnormality, a read abnormality, or an erase abnormality in the semiconductor memory, and
the control device is configured to control access of the semiconductor memory.

20. The evaluation device according to claim 11,
wherein the first information includes at least one of a defect of a resistance value, a disconnection of a specific wiring, a short circuit, or a leak of a specific wiring.
